(19) United States
(12) Patent Application Publication
(10) Pub. No.: US 2025/0047262 A1
(43) Pub. Date: Feb. 6, 2025

(54) ACOUSTIC DEVICES WITH INTEGRATED CIRCUIT ELEMENTS AND RELATED FABRICATION METHODS

(71) Applicant: QUALCOMM Incorporated, San Diego, CA (US)

(72) Inventors: Je-Hsiung Lan, San Diego, CA (US); Jonghae Kim, San Diego, CA (US); Ranadeep Dutta, Del Mar, CA (US)

(21) Appl. No.: 18/363,233

(22) Filed: Aug. 1, 2023

(51) Int. Cl. H03H 9/25; H03H 3/08; H03H 9/145; H03H 9/64

(52) U.S. Cl. CPC H03H 9/25; H03H 3/08; H03H 9/145; H03H 9/64

(57) ABSTRACT

An acoustic device includes circuit elements, such as analog circuit components, between the first and second substrate and coupled to an acoustic resonator to form an acoustic filter within the acoustic device. In some examples, forming the circuit elements between the first substrate and the second substrate includes forming the first circuit elements in insulating material on the second substrate before coupling the second substrate to a first side of the first substrate. The circuit elements disposed between the first and second substrates may include capacitors, inductors, and electrical interconnects coupled to the acoustic resonator on the first substrate. Additional features may be included in the insulating material. The acoustic device avoids the need for bulky analog components coupled to the acoustic resonator via long interconnects through a package substrate, making it possible to reduce an acoustic device's package size.

### BACKGROUND

### I. Field of the Disclosure

The technology of the disclosure relates generally to acoustic wave devices and, more specifically, to improving performance and reducing the size of such devices.

### II. Background

There are a limited set of frequency bands available for wireless communication. To share these frequency bands among the many wireless devices that may be in use within a broadcast area, each type of wireless communication is allocated to specific frequency bands. To avoid interference with each other, each device needs to broadcast only within its allotted frequencies. Therefore, wireless devices include filters to limit the frequencies of signals they transmit and receive. Acoustic wave filters are a widely used technology for performing such filtering in a small-sized package. One type of acoustic filter is a surface acoustic wave (SAW) filter which includes interdigitated electrodes on a surface of a piezoelectric material, such as lithium niobate (LN) or lithium tantalate (LT). The acoustic filter may be tuned to operate within a frequency range by coupling an acoustic resonator in a circuit with analog components, such as capacitors and inductors. The acoustic filter and the other components are typically mounted on a package substrate and coupled to each other by electrical interconnects extending through or on the package substrate. These long electrical paths through the package, between the acoustic resonator and the analog components, can reduce the efficiency or quality (e.g., the Q factor) of an acoustic filter. The analog components may be made larger to compensate for losses due to such inefficiency. In addition, the larger components cause the area of the package substrate and the height of the package to increase.

### SUMMARY

Aspects disclosed in the detailed description include acoustic devices with integrated circuit elements. Related methods of fabricating acoustic devices with integrated circuit elements are also disclosed. An acoustic device includes an acoustic resonator with electrodes on a surface of a piezoelectric material on a first side of a first substrate and a second, cap substrate also disposed on the first side of the first substrate. An exemplary acoustic device includes circuit elements, such as analog circuit components, between the first and second substrate and coupled to the acoustic resonator to form an acoustic filter within the acoustic device. In some examples, forming the circuit elements between the first substrate and the second substrate includes forming the first circuit elements in insulating material on the second substrate before coupling the second substrate to the first side of the first substrate. The circuit elements disposed between the first and second substrates may include, for example, capacitors, inductors, and electrical interconnects coupled to the acoustic resonator on the first substrate. In other examples, additional features may be included in the insulating material. In this regard, the acoustic device avoids the need for bulky analog components coupled to the acoustic resonator via long interconnects through a package substrate, making it possible to reduce an acoustic device's package size.

In this regard, in one exemplary aspect, a device is disclosed. The device includes a first substrate comprising a first surface comprising a piezoelectric material, a first electrode disposed on the first surface, and a second substrate. The device further includes a first via extending through the second substrate and coupled to the first electrode and a first circuit element electrically coupled to the first via and disposed between the second substrate and the first surface of the first substrate.

In another exemplary aspect, a method of fabricating a device is disclosed. The method includes forming a first substrate comprising a first surface comprising a piezoelectric material, forming a first electrode on the first surface, and forming a second substrate. The method further includes forming a first via extending through the second substrate and coupled to the first electrode and forming a first circuit element electrically coupled to the first via and between the second substrate and the first surface of the first substrate.

In another exemplary aspect, an acoustic filter package is disclosed. The acoustic filter package includes a package substrate and a device. The device includes a first substrate comprising a first surface comprising a piezoelectric material, a first electrode disposed on the first surface, and a second substrate. The device further includes a first via extending through the second substrate and coupled to the first electrode and a first circuit element electrically coupled to the first via and disposed between the second substrate and the first surface of the first substrate and a contact coupling the first via to the package substrate.

### BRIEF DESCRIPTION OF THE DRAWINGS

FIG. 1 is a cross-sectional side view of a first example of an exemplary acoustic filter package comprising an acoustic device on a package substrate, the acoustic device comprising a first acoustic resonator on a first substrate coupled to circuit elements in an insulating material between the first substrate and a second substrate to form an acoustic filter;

FIG. 2A is a cross-sectional side view of a conventional acoustic filter package, including an acoustic resonator device coupled to bulky analog components on a package substrate to form an acoustic filter;

FIG. 2B is a cross-sectional top view of the acoustic filter package in FIG. 2A, illustrating a plurality of resonators in a same air cavity coupled to the bulky analog components to form a single acoustic filter;

FIG. 3 is a cross-sectional side view of a second example of an exemplary acoustic filter package comprising an acoustic device on a package substrate, the acoustic device includes, in addition to the circuit elements, resonators in two air cavities for two different acoustic filters;

FIG. 4 is a cross-sectional top view of an exemplary acoustic device, including resonators in separate air cavities and circuit elements providing multiple acoustic filters;

FIG. 5 is a cross-sectional side view in another example of an acoustic device including circuit elements for acoustic filters and external connections coupled to the acoustic filters through a cap substrate by cylindrical vias having non-conductive cores;

FIG. 6 is a flowchart of an exemplary method of fabricating the acoustic device in FIG. 1;

FIGS. 7A-7H are cross-sectional side views of the fabrication stages of an exemplary acoustic device, including a resonator and circuit elements for an acoustic filter;

FIGS. 8A-8H are a flow chart of a method of fabricating an acoustic device, including an acoustic resonator and circuit elements of an acoustic filter, as illustrated in the fabrication stages shown in FIGS. 7A-7H;

FIG. 9 is a block diagram of an exemplary wireless communication device that includes an acoustic device comprising a first acoustic resonator on a first substrate coupled to circuit elements in an insulating material between the first substrate and a second substrate to form an acoustic filter as shown in FIGS. 1, 3-5 and 7A-7H and according to, but not limited to, any of the exemplary fabrication processes of fabricating such acoustic device in FIGS. 6 and 8A-8H; and

FIG. 10 is a block diagram of an exemplary processor-based system that can include an acoustic device comprising a first acoustic resonator on a first substrate coupled to circuit elements in an insulating material between the first substrate and a second substrate to form an acoustic filter as shown in FIGS. 1, 3-5 and 7A-7H and according to, but not limited to, any of the exemplary fabrication processes of fabricating such acoustic device in FIGS. 6 and 8A-8H.

### DETAILED DESCRIPTION

Several exemplary aspects of the present disclosure are described in reference to the drawing figures. The word “exemplary” is used herein to mean “serving as an example, instance, or illustration.” Any aspect described herein as “exemplary” is not necessarily to be construed as preferred or advantageous over other aspects.

Aspects disclosed in the detailed description include acoustic devices with integrated circuit elements. Related methods of fabricating acoustic devices with integrated circuit elements are also disclosed. An acoustic device includes an acoustic resonator with electrodes on a surface of a piezoelectric material on a first side of a first substrate and a second, cap substrate also disposed on the first side of the first substrate. An exemplary acoustic device includes circuit elements, such as analog circuit components, between the first and second substrate and coupled to the acoustic resonator to form an acoustic filter within the acoustic device. In some examples, forming the circuit elements between the first substrate and the second substrate includes forming the first circuit elements in insulating material on the second substrate before coupling the second substrate to the first side of the first substrate. The circuit elements disposed between the first and second substrates may include, for example, capacitors, inductors, and electrical interconnects coupled to the acoustic resonator on the first substrate. In other examples, additional features may be included in the insulating material. In this regard, the acoustic device avoids the need for bulky analog components coupled to the acoustic resonator via long interconnects through a package substrate, making it possible to reduce an acoustic device's package size.

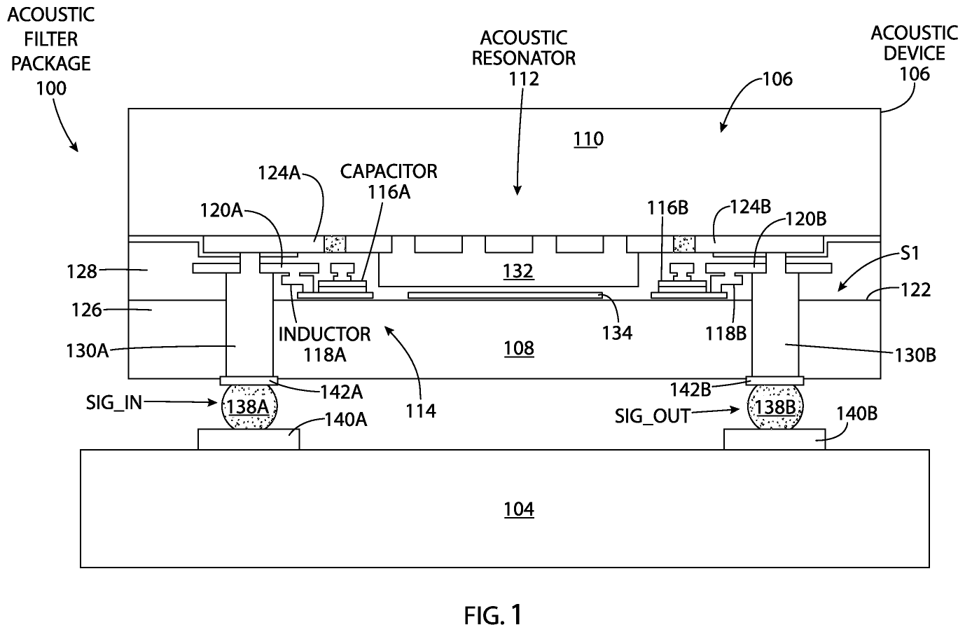

FIG. 1 is a cross-sectional side view of an exemplary acoustic filter package 100, including an acoustic device 102 disposed on a package substrate 104. The acoustic device 102 includes an acoustic filter 106 formed between a first, base substrate 108 and a second, cap substrate 110. The acoustic filter 106 includes a first acoustic resonator 112 coupled to (analog) circuit elements 114, including capacitors 116A, 116B, inductors 118A, 118B, and interconnects 120A, 120B. Thus, in addition to the first acoustic resonator 112, the circuit elements 114 are also disposed between the base substrate 108 and the cap substrate 110.

In this example, the first acoustic resonator 112 is a surface acoustic wave (SAW) resonator formed on a first surface 122 of the base substrate 108. The first acoustic resonator 112 includes a first electrode 124A and a second electrode 124B, which may be interdigitated electrodes, on the first surface 122. The circuit elements 114, including the capacitors 116A and 116B, inductors 118A and 118B, and interconnects 120A and 120B, are disposed within an insulating material 128 between the base substrate 108 and the cap substrate 110.

The first surface 122 comprises a piezoelectric material 126, such as lithium niobate (LN), lithium tantalate (LT), or any suitable piezoelectric material. The piezoelectric material 126 may be in a layer on a first side S1 of the base substrate 108. In such an example, the base substrate 108 includes another material on which the layer of the piezoelectric material 126 is formed. In another example, the base substrate 108 is a monolithic substrate of LN or LT such that the first surface 122 of the piezoelectric material 126 is not merely a layer on a substrate of a second material. Forming the base substrate 108 may include fabricating or manufacturing the base substrate 108 or, alternatively, providing the first substrate 108 comprising the piezoelectric material 126 for assembly.

An input signal SIG_IN having an oscillating voltage, applies a voltage between the first and second electrodes 124A and 124B, which causes the piezoelectric material 126 to expand and contract to produce acoustic waves in the first surface 122. The acoustic waves have a resonant frequency as part of the frequency filtration. An output signal SIG_OUT is generated from the acoustic waves on the piezoelectric material 126. Operation of a SAW resonator is well-known by persons of skill in the art and is not described in further detail here.

To “tune” the output signal SIG_OUT to a desired frequency or frequency range, the first acoustic resonator 112 is coupled in a circuit including the circuit elements 114, which includes the capacitor 116A, the inductor 118A, and the interconnect 120A. In this example, the interconnect 120A couples the acoustic filter 106 to a first vertical interconnect access (via) 130A that provides a connection to the package substrate 104. The package substrate 104 includes interconnects (not shown) to couple the acoustic device 102 to external circuits (not shown). The acoustic device 102 also includes a second via 130B, which is coupled to the second electrode 124B, and may further be coupled to the capacitor 116B and/or the inductor 118B by the interconnect 120B. The

As explained in more detail below, the circuit elements 114 are formed in the insulating material 128 during fabrication of the acoustic device 102. An air cavity 132 is formed in the insulating material 128 between the first and second electrodes 124A and 124B and the cap substrate 110. Thus, the insulating material 128 surrounds the first acoustic resonator 112. The air cavity 132 is provided to allow the acoustic waves in the piezoelectric material 126 to propagate without external interference. In addition, the acoustic device 102 may include, as shown in this example, an electromagnetic interference (EMI) shield 134. The EMI shield 134 is disposed on the cap substrate 110 on a side of the air cavity 132 opposite the first and second electrodes 124A, 124B. The EMI shield is coupled to a terminal (not shown) of the acoustic device 102 that is configured to couple to a reference voltage rail receiving a reference voltage, such as a ground voltage (GND or Vss). The EMI shield 134 provides some protection of the first acoustic resonator 112 from external radiation that may cause noise or signal interference in the output signal SIG_OUT.

Also shown in FIG. 1 are bumps or solder balls 138A and 138B coupling the vias 130A and 130B to package contacts 140A and 140B on the package substrate 104. In the example shown here, the acoustic filter package 100 includes device contacts 142A and 142B on the cap substrate 110 to couple the solder balls 138A and 138B to the vias 130A and 130B. Thus, the device contacts 142A and 142B are configured to couple the first and second electrodes 124A and 124B to an external circuit. Here, the vias 130A and 130B are cylindrical or substantially cylindrical in shape and are formed monolithically from a solid conductive metal. In some examples, the solder balls 138A and 138B may couple directly to the vias 130A and 130B without the device contacts 142A and 142B. The acoustic filter package 100 may be employed in a wireless device.

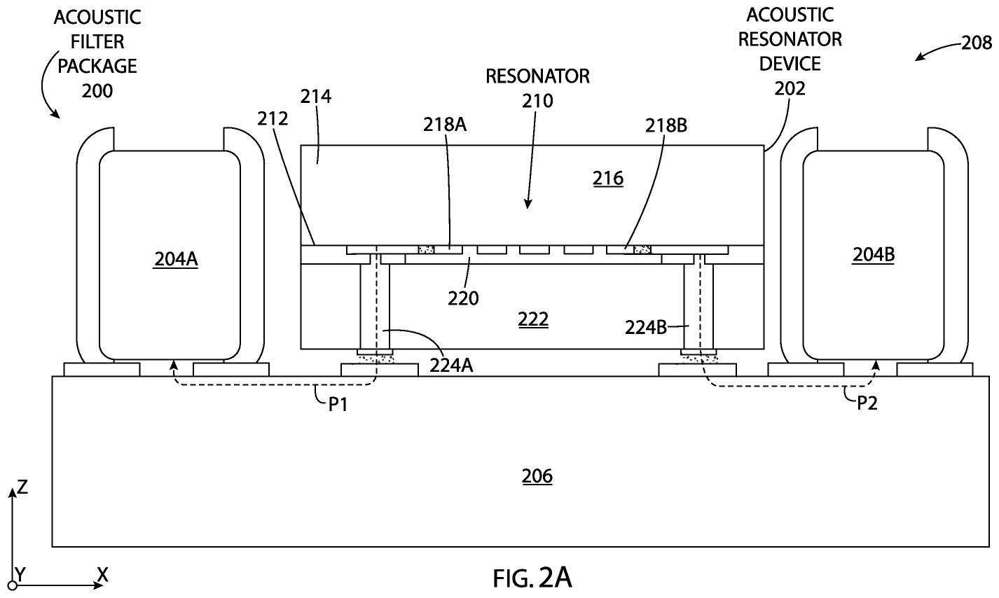

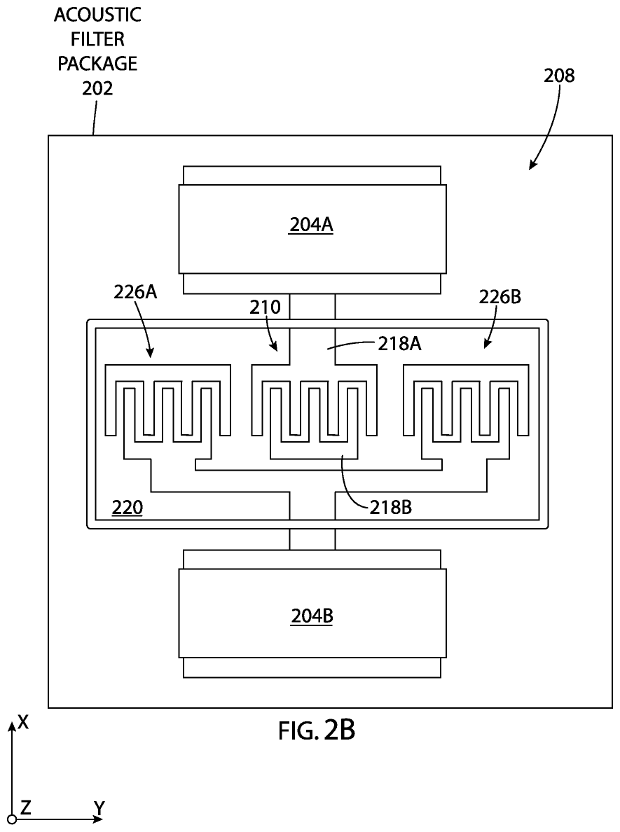

FIG. 2A is a cross-sectional side view of a conventional acoustic filter package 200, including an acoustic resonator device 202 coupled to analog circuit elements 204A and 204B on a package substrate 206 to form an acoustic filter 208. Although not shown, the package substrate 206 includes interconnects on a surface or in internal layers to couple the acoustic resonator device 202 to the analog circuit elements 204A and 204B. The analog circuit elements 204A and 204B may be capacitors or inductors.

The acoustic resonator device 202 includes a resonator 210 on a surface 212 of a piezoelectric material 214 on a base substrate 216. The resonator 210 includes electrodes 218A and 218B on the surface 212 within an air cavity 220 formed between the surface 212 and a cap substrate 222. In some examples, the cap substrate 222 may be a glass substrate. The acoustic resonator device 202 includes through glass vias (TGVs) 224A and 224B that extend through the cap substrate 222 and couple to the electrodes 218A and 218B, respectively.

The acoustic filter 208 includes the resonator 210 coupled in a circuit to the analog circuit elements 204A and 204B. In this regard, the package substrate 206 is made larger to make room for the analog circuit elements 204A and 204B, in addition to the resonator 210. Because the circuit elements 114 in the acoustic filter package 100 in FIG. 1 are formed inside the acoustic device 102, between the first substrate 108 and the cap substrate 110, the acoustic filter package 100 does not need to include bulk analog components. Therefore, the package substrate 104 in FIG. 1 may be smaller in area than the package substrate 206 in FIG. 2.

The acoustic filter 208 includes electrical path P1 through the TGV 224A between the electrode 218A and the package substrate 206 and through an interconnect in/on the package substrate 206 between the acoustic resonator device 202 and the analog circuit element 204A. Similarly, an electrical path P2 of the acoustic filter 208 extends through the TGV 224B from between the electrode 218B to the package substrate 206 and through an interconnect in/on the package substrate 206 to the analog circuit element 204B. The electrical paths P1 and P2 are much longer than the distances within the acoustic filter 106 in FIG. 1. Consequently, even if the paths P1 and P2 extend through large copper interconnects intended to have minimal resistance, the lengths of the paths P1 and P2 still cause losses, reducing efficiency and contributing to a low Q factor in the acoustic filter package 200. In addition, because of such losses, greater capacitance and/or inductance are needed, making it necessary to have analog circuit elements 204A and 204B that are larger in size than the circuit elements 114 in FIG. 1. In some examples, the analog circuit elements 204A and 204B may be taller (e.g., in a Z-axis direction) than the acoustic resonator device 202.

FIG. 2B is a cross-sectional top view of the acoustic filter package 200 in FIG. 2A. This view shows the analog circuit elements 204A and 204B and the interior of the air cavity 220 in the acoustic resonator device 202. In this example, in addition to the electrodes 218A and 218B of the resonator 210 shown in FIG. 2A, the air cavity 220 also contains resonators 226A and 226B. However, because the resonators 210, 226A, and 226B are all disposed in the same air cavity 220 and coupled to the analog circuit elements 204A and 204B, they are all part of the same acoustic filter 208. Resonators for different filters, having different resonant frequencies or frequency ranges, would interfere with each other if disposed within a same air cavity. Therefore, because the acoustic resonator device 202 is limited to one air cavity 220, the acoustic resonator device 202 may provide resonator(s) 210, 226A, and 226B for only one acoustic filter 208.

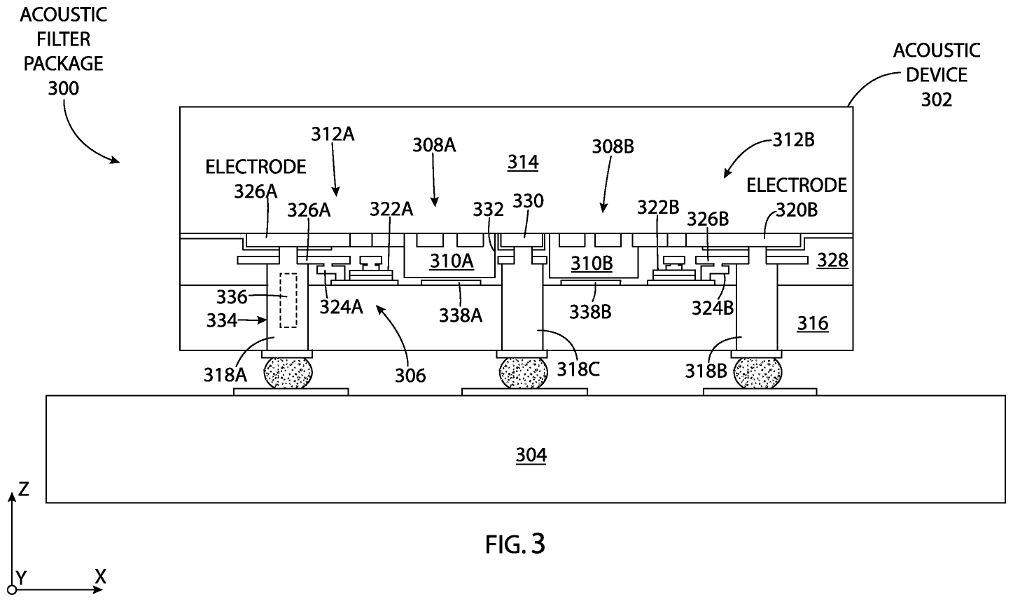

FIG. 3 is a cross-sectional side view of an exemplary acoustic filter package 300 comprising an acoustic device 302 on a package substrate 304, and the acoustic device 302 includes circuit elements 306 and resonators 308A and 308B in respective air cavities 310A and 310B to form two acoustic filters 312A and 312B.

The acoustic filter package 300 corresponds in many aspects to the acoustic filter package 100 in FIG. 1, having all the beneficial features described above with respect to FIG. 1, such as the circuit elements 306 between a first, base substrate 314 and a second, cap substrate 316 to avoid the need for externally coupled analog circuit elements that increase package size and reduce circuit efficiency. However, in another exemplary aspect, the acoustic filter package 300 includes two separate air cavities 310A and 310B, each including one of the resonators 308A and 308B. In this regard, unlike the conventional acoustic resonator device 202 in FIGS. 2A and 2B, which is limited to one air cavity 228 housing one or more of the resonators 210, 226A, and 226B of a single acoustic filter 208, the resonators 308A and 308A in the acoustic device 302 are provided in separate air cavities 310A and 310B and may resonate at different (e.g., first and second) resonant frequencies. In this regard, the acoustic device 302 can include two separate acoustic filters 312A and 312B directed to different frequency ranges. The acoustic filters 312A and 312B may be directed to different frequencies or frequency ranges and may work cooperatively to provide more frequency options and/or better frequency control than the conventional acoustic resonator device 202 having the single air cavity 228.

The acoustic device 302 includes via 318A coupled to a first electrode 320A of the resonator 308A and via 318B coupled to a second electrode 320B of the resonator 308B. The resonator 308A further includes a third electrode (not shown) in the air cavity 310A and the reasonable 308B includes a fourth electrode (not shown) in the air cavity 310B. The vias 318A and 318B are also coupled to the circuit elements 306, which include capacitors 322A, 322B, inductors 324A, 324B, and interconnects 326A, 326B. The vias 318A, 318B extend through an insulating material 328 and through the cap substrate 316 to couple to the package substrate 304. Similarly, the acoustic device 302 includes via 318C, which couples to a node 330, which may further couple one or both of the resonators 308A, 308B. The via 318C is disposed within a wall 332 formed of the insulating material 328. The wall 332 provides separation between the air cavities 310A and 310B. The via 318C extends from the node 330, through the wall 332, and through the cap substrate 316 to couple to the package substrate 304.

In the acoustic filter package 300, the vias 318A-318C may be cylindrical or substantially cylindrical and monolithic metal vias, where monolithic means that a same conductive metal or other conductive material extends through a cross-section of the vias 318A-318C from an external surface 334 to a core region 336.

The air cavities 310A and 310B also include EMI shields 338A and 338B for providing protection from noise interference to the acoustic filters 312A and 312B.

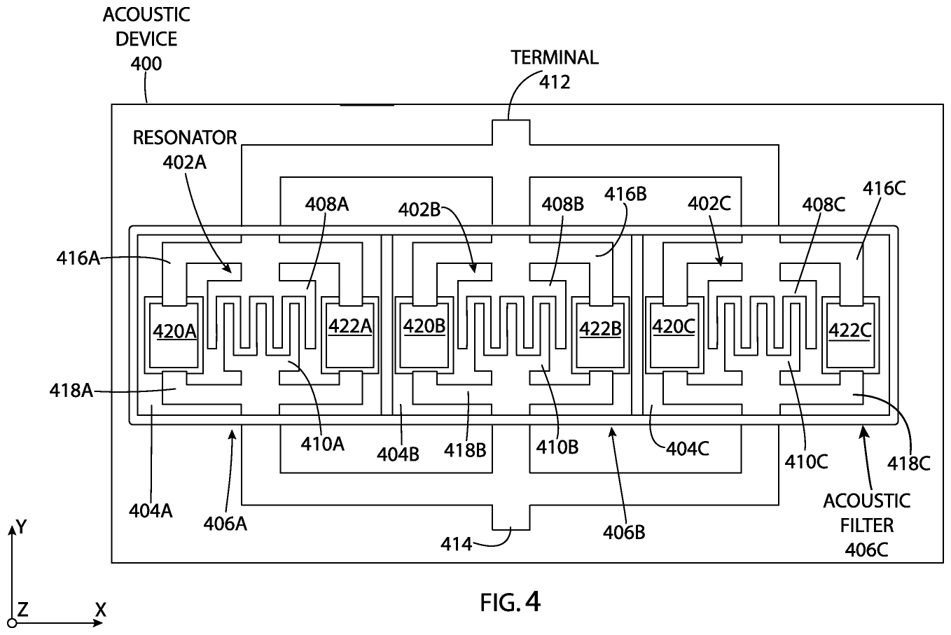

FIG. 4 is a cross-sectional top view of an exemplary acoustic device 400, including resonators 402A-402C in separate air cavities 404A-404C for multiple acoustic filters 406A-406C. The air cavity 404A includes electrodes 408A and 410A, which are coupled, respectively, to terminals 412 and 414 by interconnects 416A and 418A. Interconnects 416A and 418A also couple the electrodes 408A and 410A to, for example, a capacitor 420A and an inductor 422A. The capacitor 420A and the inductor 422A are coupled to the resonator 402A to control the frequencies that are filtered by the acoustic filter 406A, as known in the art. Including circuit elements such as the interconnects 416A, 418A, the capacitor 420A, and the inductor 422A within the acoustic device 400, reduce the overall size of an acoustic filter package by reducing a number of devices disposed on a package substrate (not shown) and also improve the quality factor of the acoustic filter 406A.

Similar to the air cavity 404A, the air cavities 404B and 404C enclose respective electrodes 408B, 410B, and 408C, 410C, respectively. The acoustic filters 406B and 406C include interconnects 416B, 418B and 416C, 418C, respectively, to couple the resonators 402B, 402C to capacitors 420B, 420C, and inductors 422C, 422C. In FIG. 4, each of the acoustic filters 406A-406C are coupled to the terminals 412 and 414. Thus, the acoustic filters 406A-406C may have different resonant frequencies to provide separate filtration control of a signal.

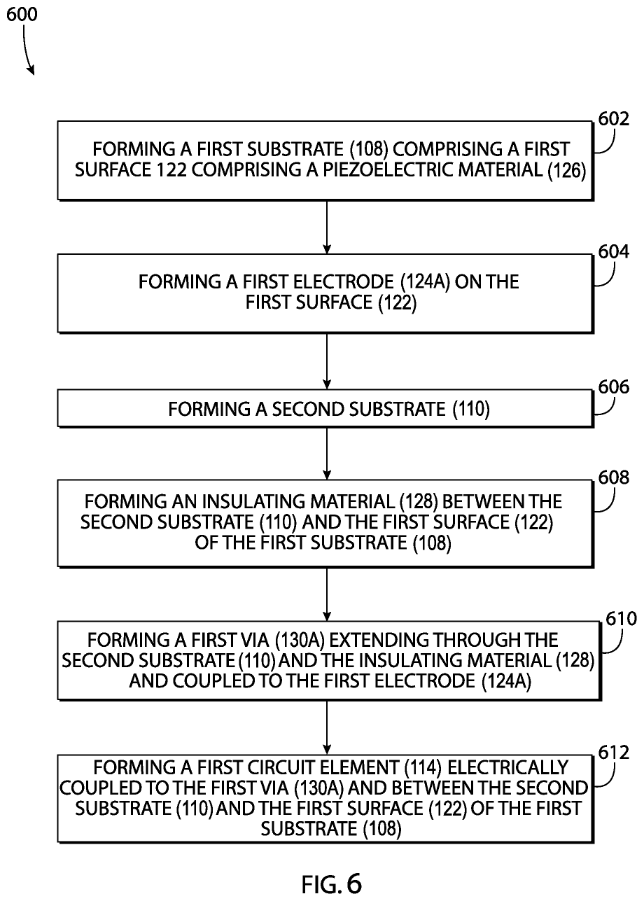

In some examples not shown, the acoustic filters 406A-406C may not be coupled together (e.g., to the terminals 412 and 414) to cooperatively filter a same signal. Rather, in some examples, there may be additional terminals (not shown) providing separate signals to be filtered by the acoustic filters 406A-406C. It should be understood that acoustic filter devices, as disclosed herein, are not limited to the examples shown. That is, the numbers of air cavities, as well as the shapes, relative sizes, and spatial arrangements of the air cavities illustrated herein, are merely examples. Alternative and/or additional air cavities, resonators, and corresponding filter circuit elements are made possible by the method of fabricating the acoustic filter devices disclosed herein, as described in more detail below with reference to FIGS. 6 and 8A-8H.

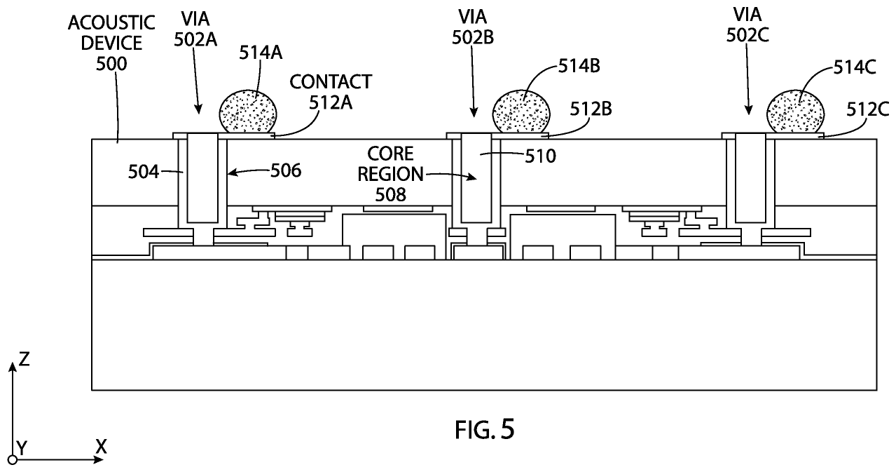

FIG. 5 is a cross-sectional side view of another example of an acoustic device 500. The acoustic device 500 corresponds to the acoustic device 302 in FIG. 3 in all aspects, except as follows, so descriptions and labeling of the features of FIG. 5 are not provided separately here. As noted above, the vias 318A-318C of the acoustic device 302 are monolithic. In contrast, as another example, the acoustic device 500 includes vias 502A-502C that are not monolithic. Rather, the vias 502A-502C may also be cylindrical or substantially cylindrical but have a cylindrical layer of a conductive metal 504 or other conductive material at external surface 506, while a core region 508 includes a non-conductive fill material 510. The fill material 510 may be a dry film material, which may be an epoxy based photoresist, such as a photosensitive permanent film. Contacts 512A-512C are coupled, respectively, to the vias 502A-502C to provide a point of contact for bumps or solder balls 514A-514C, which may be employed to couple the acoustic device 500 to a package substrate (not shown), for example.

Vias such as the vias 502A-502C, as well as other exemplary and beneficial aspects of the acoustic filter devices disclosed herein, are described in more detail in reference to the description of an exemplary method of fabrication of acoustic filter devices provided below.

It should be understood that the acoustic devices 102, 302, 400, and 500, having respective resonators and circuit elements, such as analog circuit elements, may internally include all the components of acoustic filters and, therefore, may also be referred to as acoustic filter devices.

FIG. 6 is a flowchart of an exemplary method 600 of fabricating the acoustic filter devices illustrated in FIGS. 1 and 3-5. The method 600 includes forming a first substrate 108 comprising a first surface 122 comprising a piezoelectric material 126 (block 602). As used herein, “forming a first substrate” is not limited to fabricating or manufacturing the first substrate and may additionally or alternatively include providing the first substrate for assembly. The method 600 also includes forming a first electrode 124A on the first surface 122 (block 604). The method further includes forming a second substrate 110 (block 606) and forming an insulating material 128 between the second substrate 110 and the first surface 122 of the first substrate 108 (block 608). The method 600 also includes forming a first via 130A extending through the second substrate 110 and the insulating material 128 and coupled to the first electrode 124A (block 610); and forming a first circuit element 114 electrically coupled to the first via 130A and between the second substrate 110 and the first surface 122 of the first substrate 108 (block 612).

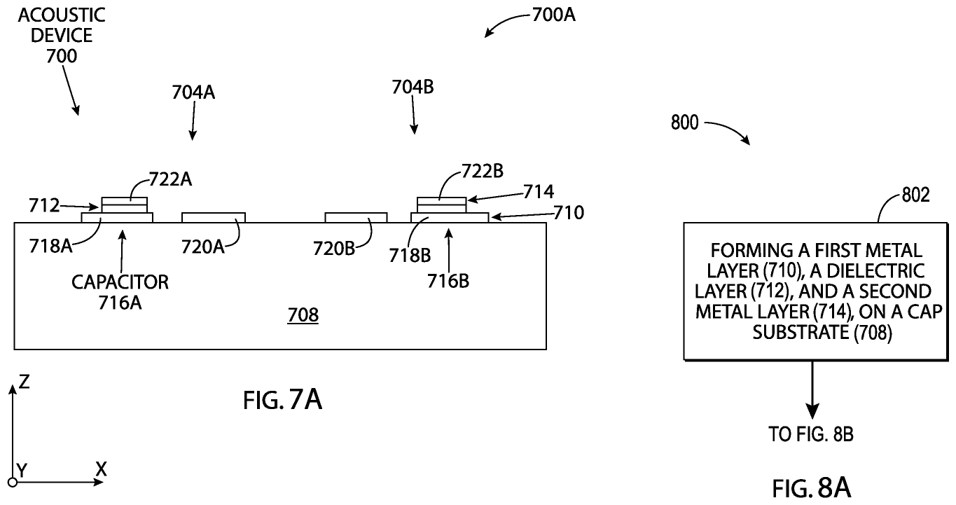

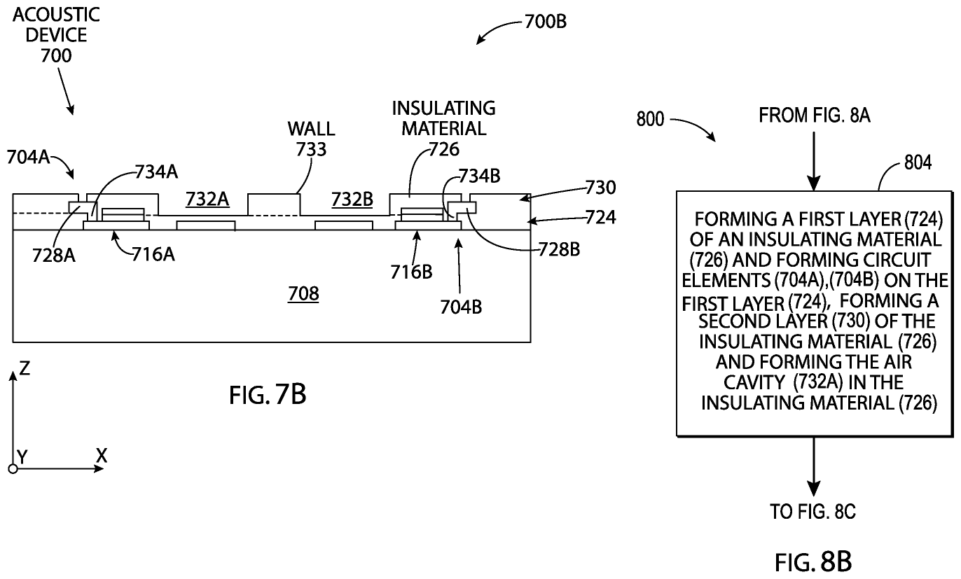

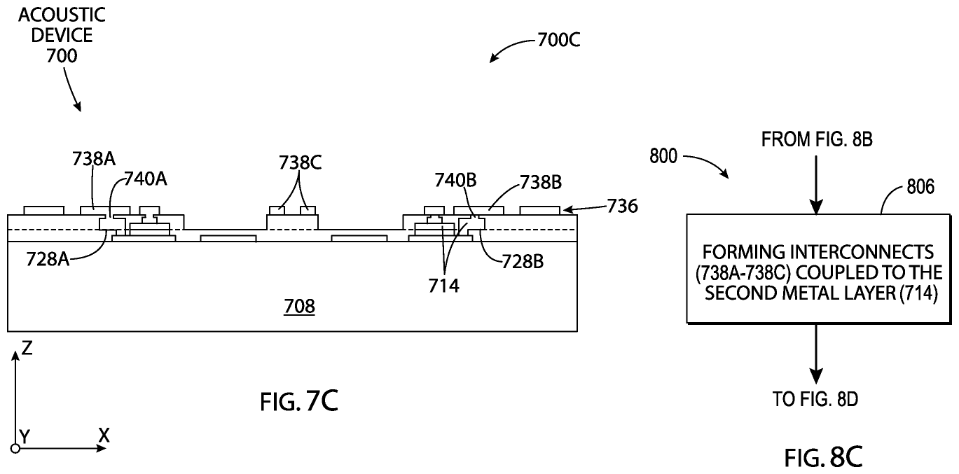

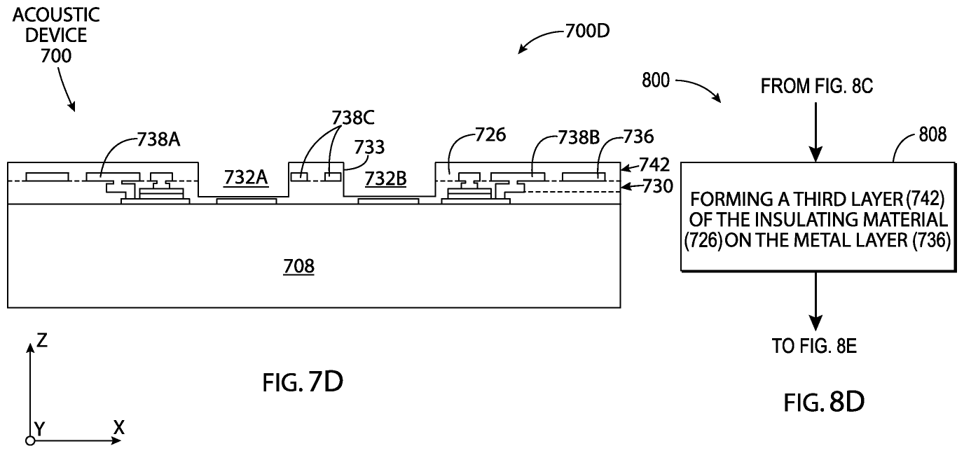

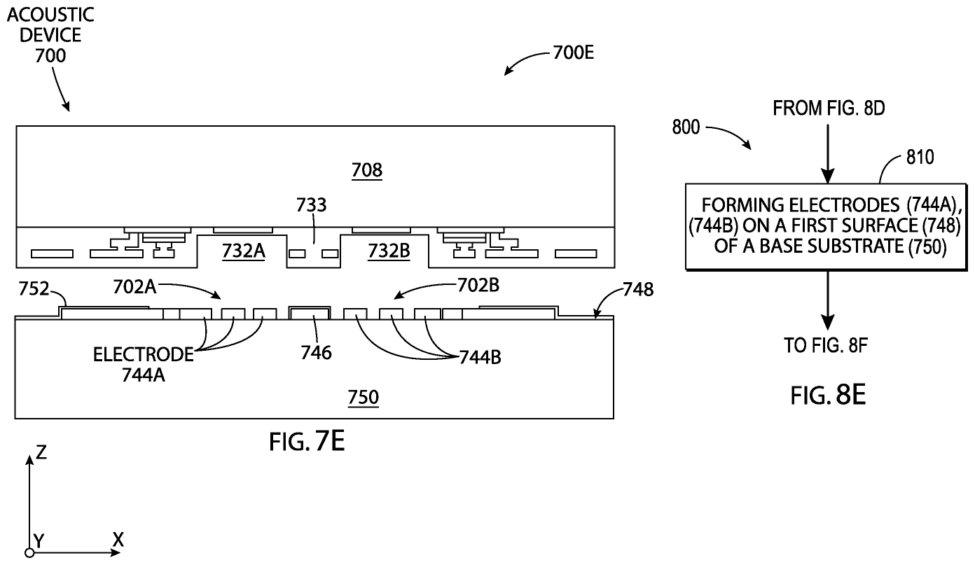

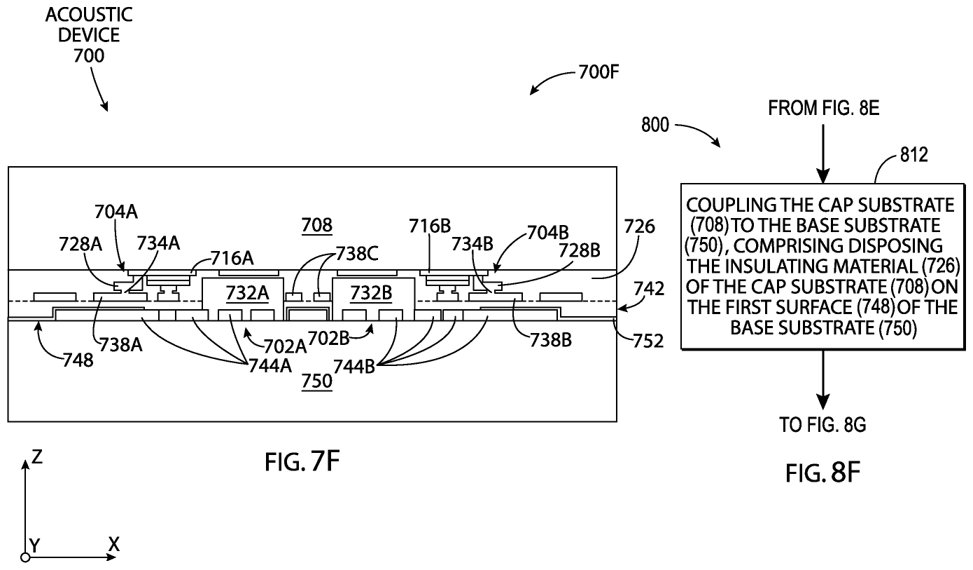

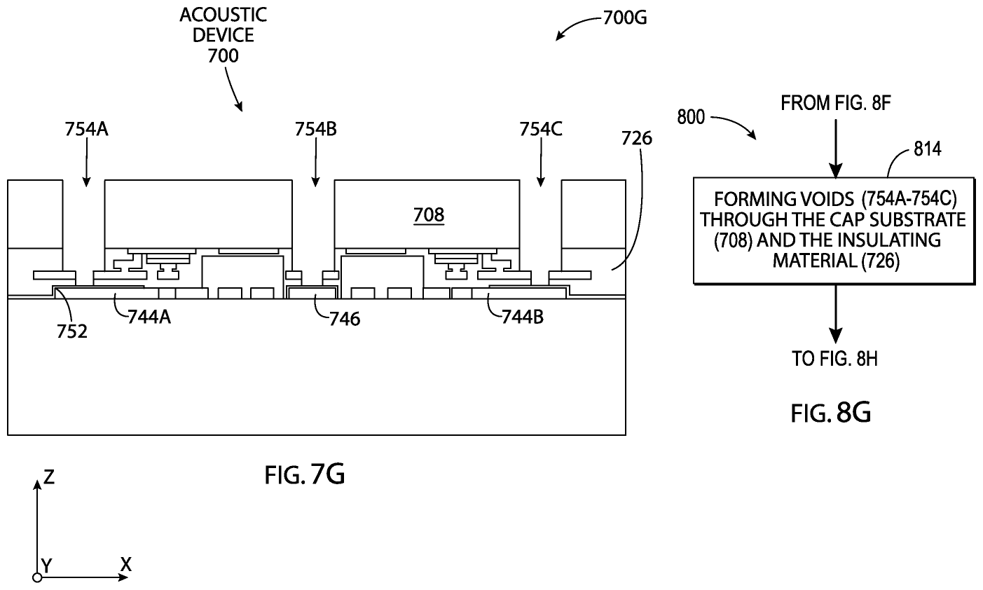

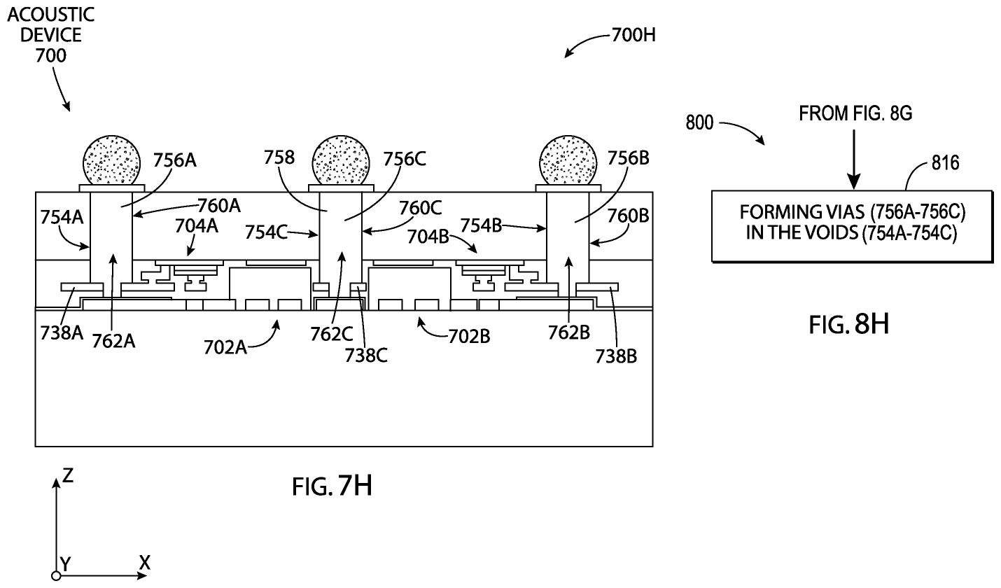

FIGS. 7A-7H are cross-sectional side views of an exemplary acoustic device 700, including resonators 702A, 702B and circuit elements 704A, 704B for acoustic filters 706A, 706B in fabrication stages 700A-700H. The fabrication stages 700A-700H in FIGS. 7A-7H in a method 800 of fabricating the acoustic device 700 are described in corresponding blocks 802-816 of a flowchart in FIGS. 8A-8H. For example, the fabrication stage 700A illustrated in FIG. 7A is described in the corresponding flowchart block 802.

FIG. 7A shows a cap substrate 708 corresponding to the cap substrate 110 in FIG. 1. The cap substrate 708 may also be referred to as a hybrid integrated passive (HIP) substrate because the material of the cap substrate 708 employed in a SAW filter provides multiple benefits, which include, in a first aspect, forming circuit elements 704A, 704B (e.g., passive circuit elements) thereon. In a second aspect, the cap substrate 708 comprises a high thermal conductivity material, such as alumina, high-resistivity silicon (HRS), porous silicon (pSi), etc., having a thermal conductivity exceeding thirty (20) watts per meter-kelvin (W/(m·K)), in some cases having a thermal conductivity exceeding thirty (30) watts per meter-kelvin (W/(m·K)). The cap substrate 708 may have a thickness in a range of sixty (60) to one hundred twenty-five (125) microns. A higher thermal conductivity improves the dissipation, through the thickness of the cap substrate 708, of heat that is generated by the acoustic activity in a SAW filter. Having improved thermal conductivity makes a SAW filter more suitable for operation in a high-power transmission circuit or device, for example. In some examples, the thermal conductivity of the cap substrate 708 may exceed ten (10) watts per meter-kelvin (W/(m·K)). In some examples, the thermal conductivity of the cap substrate 708 may be at least twenty (20) watts per meter-kelvin (W/(m·K)). In a third aspect, the cap substrate 708 may be thinned to a greater extent than other previously employed cap substrates, such as glass, which makes it possible to reduce a height of the acoustic device 700 compared to conventional acoustic resonator devices.

Block 802 includes forming a first metal layer 710, a dielectric layer 712, and a second metal layer 714 on the cap substrate 708, as shown in FIG. 7A. The first metal layer 710 is formed on the cap substrate 708. In this example, the dielectric layer 712 is formed on portions of the first metal layer 710, and the second metal layer 714 is formed on the dielectric layer 712. Photo-lithographic methods may be employed in this regard. The first metal layer 710 and the second metal layer 714 may be copper (Cu) or another highly conductive metal. The first metal layer 710, the dielectric layer 712, and the second metal layer 714, together form capacitors 716A and 716B. First electrodes 718A and 718B of the capacitors 716A, 716B are formed in the first metal layer 710. EMI shields 720A and 720B are also formed in the first metal layer 710 in this example. The EMI shields 720A, 720B correspond to respective air cavities, shown below, for the resonators 702A, 702B. The second metal layer 714 provides second electrodes 722A and 722B, separated from the first electrodes 718A, 718B of the capacitors 716A and 716B by the dielectric layer 712. In this regard, the capacitors 716A and 716B may be metal-insulator-metal (MIM) capacitors. Thus, forming the first and second metal layers 710 and 714 and the dielectric layer 712 may further comprise forming the EMI shields 720A and 720B and the capacitors 716A and 716B on the cap substrate 708.

FIG. 7B illustrating the acoustic device 700 at the fabrication stage 700B, shows additional features formed on the cap substrate 708, as described with reference to corresponding block 804 of the method 800. Block 804 includes forming a first layer 724 of an insulating material 726 and forming circuit elements 704A, 704B on the first layer 724. The circuit elements 704A, 704B are formed of metal and may include inductors 728A and 728B. The inductors 728A and 728B may be formed as two-dimensional (2D) inductors (e.g., planar spiral patterns). The insulating material 726 may be a polymer, such as polyimide.

Block 804 further includes forming a second layer 730 of the insulating material 726 and forming the air cavity 732A in the insulating material 726. Block 804 optionally may include forming an air cavity 732B and a wall 733 separating the air cavities 732A and 732B. Forming the air cavities 732A and 732B includes patterning the second layer 730 to form the wall 733. The first layer 724 is further patterned to form vertical interconnects 734A, 734B, and the first and second layers 724, 730 may also be patterned to couple the capacitors 716A, 716B and the inductors 728A and 728B to electrodes (see FIG. 7E) in the resonators 702A and 702B.

FIG. 7C illustrates the fabrication stage 700C, including more features formed on the cap substrate 708 in a metal layer 736, as described with reference to block 806C of the method 800. Block 806 includes forming interconnects 738A-738C coupled to the second metal layer 714, which may also include forming vertical interconnects 740A and 740B to the inductors 728A and 728B. The third metal layer 736 includes the interconnects 738A-738C and may be disposed parallel to the cap substrate 708. The interconnects 738A and 738B may be electrically coupled to the resonators 702A and 702B in FIG. 7E.

FIG. 7D illustrates fabrication stage 700D corresponding to block 808 in method 800. Block 808 includes forming a third layer 742 of the insulating material 726 on the metal layer 736. The third layer 742 is formed on the interconnects 738A-738C and on the second layer 730, which includes the wall 733 and regions outside the air cavities 732A, 732B.

FIG. 7E illustrates fabrication stage 700E corresponding to block 810 in method 800. Block 810 includes forming electrodes 744A, 744B on a first surface 748 of a base substrate 750. In some examples, block 810 includes forming a node 746 opposite to the wall 733 may be coupled to one or both resonators 702A, 702B. A passivation layer 752 may also be formed on the base substrate 750. The passivation layer 752 may be silicon nitride (SiN), for example. As shown in FIG. 7E, the cap substrate 708 is disposed opposite to the first surface 748 of the base substrate 750. In particular, the air cavities 732A and 732B are aligned opposite to the electrodes 744A and 744B prior to coupling the base substrate 750 and the cap substrate 708, as shown in FIG. 7F.

FIG. 7F illustrates the acoustic device 700 at fabrication stage 700F, which corresponds to block 812 in method 800. Block 812 includes coupling the cap substrate 708 to the base substrate 750, which includes disposing the insulating material 726 of the cap substrate 708 on the first surface 748 of the base substrate 750. In this regard, the third layer 742 of the insulating material 726 may be in contact with the passivation layer 752 and portions of the electrodes 744A, 744B. Thus, the third layer 742 of the insulating material 726 is between the circuit elements 704A, 704B, and the first surface 748, and the air cavities 732A and 732B enclose the resonators 702A and 702B.

The circuit elements 704A include the capacitor 716A, the inductor 728A, the vertical interconnects 734A, and interconnects 738A. The circuit elements 704B include the capacitor 716B, the inductor 728B, the vertical interconnects 734B and interconnects 738B, and also include the interconnects 738C. The circuit elements 704A, 704B may include additional capacitors, inductors, and interconnects not shown here, in addition to other circuit features that may be formed in the insulating material 726.

FIG. 7G is an illustration of fabrication stage 700G corresponding to block 814 of the method 800. Block 814 includes forming through substrate via (TSuV) voids (“voids”) 754A-754C through the cap substrate 708 and the insulating material 726 (and passivation layer 752). The voids 754A, 754B extend to the electrodes 744A and 744B. The TSuV void 754C extends to node 746 in this example. The voids may be cylindrical or substantially cylindrical.

FIG. 7H is an illustration of fabrication stage 700H corresponding to block 816 of the method 800. Block 816 includes forming vias 756A-756C in the voids 754A-754C. The vias 756A-756C are electrically coupled to the interconnects 738A-738C, respectively, providing electrical paths to the acoustic resonators 702A, 702B and the circuit elements 704A, 704B. Forming the vias 756A-756C may include deposition of a metal 758, which may include vapor deposition or another appropriate process such that the metal 758 first adheres to sides 760A-760C of the voids 754A-754C.

In this example, which corresponds to the examples in FIGS. 1 and 3, the deposition process continues until the voids are filled to their cores 762A-762C as monolithic vias of the metal 758. In an alternative example, forming the vias 502A-502C in FIG. 5 may include deposition of the metal 758 as described above but for a shorter period, resulting in layers of the metal 758 on the sides 760A-760C of the vias 756A-756C, but the cores 762A-762C being hollow. Such hollow cylindrical vias provide sufficiently low resistance electrical paths to external circuits. Thus, to save time and the metal 758, the cores 762A-762C may be filled with a non-conductive material, such as the dry film described above.

Electronic devices that include includes an acoustic device comprising a first acoustic resonator on a first substrate coupled to circuit elements in an insulating material between the first substrate and a second substrate to form an acoustic filter, as shown in FIGS. 1, 3-5, and 7A-7H and according to, but not limited to, any of the exemplary fabrication processes of fabricating such acoustic device in FIGS. 6 and 8A-8H, and according to any aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, laptop computer, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

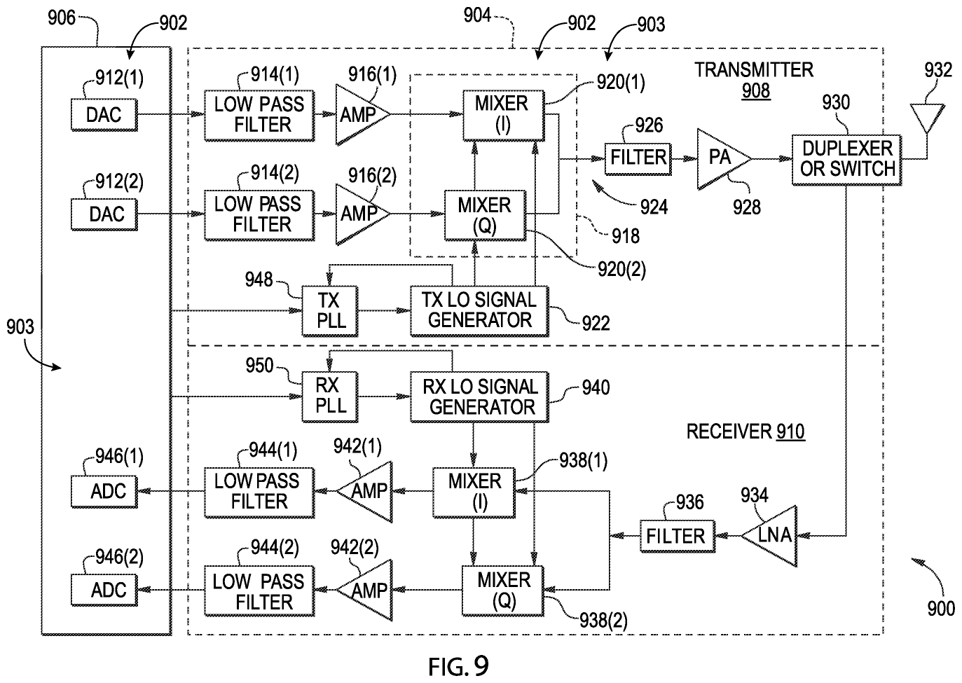

In this regard, FIG. 9 illustrates a block diagram of an exemplary wireless communications device 900 that includes radio frequency (RF) components formed from one or more ICs 902, wherein any of the ICs 902 can include an acoustic filter that includes electrodes disposed on a piezoelectric layer on a first side of a first substrate and vias extending through the substrate to couple the electrodes to a second side of the substrate as illustrated in FIGS. 1 and 4F and according to, but not limited to, any of the exemplary fabrication processes of fabricating such acoustic filter in FIGS. 3 and 5A-5F, and according to any aspects disclosed herein. The wireless communications device 900 may include or be provided as examples in any of the above-referenced devices. As shown in FIG. 9, the wireless communications device 900 includes a transceiver 904 and a data processor 906. The data processor 906 may include a memory to store data and program codes. The transceiver 904 includes a transmitter 908 and a receiver 910, which support bi-directional communications. In general, the wireless communications device 900 may include any number of transmitters 908 and/or receivers 910 for any number of communication systems and frequency bands. All or a portion of the transceiver 904 may be implemented on one or more analog ICs, RF ICs (RFICs), mixed-signal ICs, etc.

The transmitter 908 or the receiver 910 may be implemented with a super-heterodyne or direct-conversion architecture. In the super-heterodyne architecture, a signal is frequency-converted between RF and baseband in multiple stages, e.g., from RF to an intermediate frequency (IF) in one stage and then from IF to baseband in another stage. In the direct-conversion architecture, a signal is frequency-converted between RF and baseband in one stage. The super-heterodyne and direct-conversion architectures may use different circuit blocks and/or have different requirements. In the wireless communications device 900 in FIG. 9, the transmitter 908 and the receiver 910 are implemented with the direct-conversion architecture.

In the transmit path, the data processor 906 processes data to be transmitted and provides I and Q analog output signals to the transmitter 908. In the exemplary wireless communications device 900, the data processor 906 includes digital-to-analog converters (DACs) 912(1), 912(2) for converting digital signals generated by the data processor 906 into I and Q analog output signals, e.g., I and Q output currents, for further processing.

Within the transmitter 908, lowpass filters 914(1), 914(2) filter the I and Q analog output signals, respectively, to remove undesired signals caused by the prior digital-to-analog conversion. Amplifiers (AMPs) 916(1), 916(2) amplify the signals from the lowpass filters 914(1), 914(2), respectively, and provide I and Q baseband signals. An upconverter 918 upconverts the I and Q baseband signals with I and Q transmit (TX) local oscillator (LO) signals from a TX LO signal generator 922 through mixers 920(1), 920(2) to provide an upconverted signal 924. A filter 926 filters the upconverted signal 924 to remove undesired signals caused by the frequency upconversion and noise in a receive frequency band. A power amplifier (PA) 928 amplifies the upconverted signal 924 from the filter 926 to obtain the desired output power level and provides a transmit RF signal. The transmit RF signal is routed through a duplexer or switch 930 and transmitted via an antenna 932.

In the receive path, the antenna 932 receives signals transmitted by base stations and provides a received RF signal, which is routed through the duplexer or switch 930 and provided to a low noise amplifier (LNA) 934. The duplexer or switch 930 is designed to operate with a specific receive (RX)-to-TX duplexer frequency separation, such that RX signals are isolated from TX signals. The received RF signal is amplified by the LNA 934 and filtered by a filter 936 to obtain a desired RF input signal. Downconversion mixers 938(1), 938(2) mix the output of the filter 936 with I and Q RX LO signals (i.e., LO_I and LO_Q) from an RX LO signal generator 940 to generate I and Q baseband signals. The I and Q baseband signals are amplified by AMPs 942(1), 942(2) and further filtered by lowpass filters 944(1), 944(2) to obtain I and Q analog input signals, which are provided to the data processor 906. In this example, the data processor 906 includes analog-to-digital converters (ADCs) 946(1), 946(2) for converting the analog input signals into digital signals to be further processed by the data processor 906.

In the wireless communications device 900 of FIG. 9, the TX LO signal generator 922 generates the I and Q TX LO signals used for frequency upconversion, while the RX LO signal generator 940 generates the I and Q RX LO signals used for frequency downconversion. Each LO signal is a periodic signal with a particular fundamental frequency. A TX phase-locked loop (PLL) circuit 948 receives timing information from the data processor 906 and generates a control signal used to adjust the frequency and/or phase of the TX LO signals from the TX LO signal generator 922. Similarly, an RX PLL circuit 950 receives timing information from the data processor 906 and generates a control signal used to adjust the frequency and/or phase of the RX LO signals from the RX LO signal generator 940.

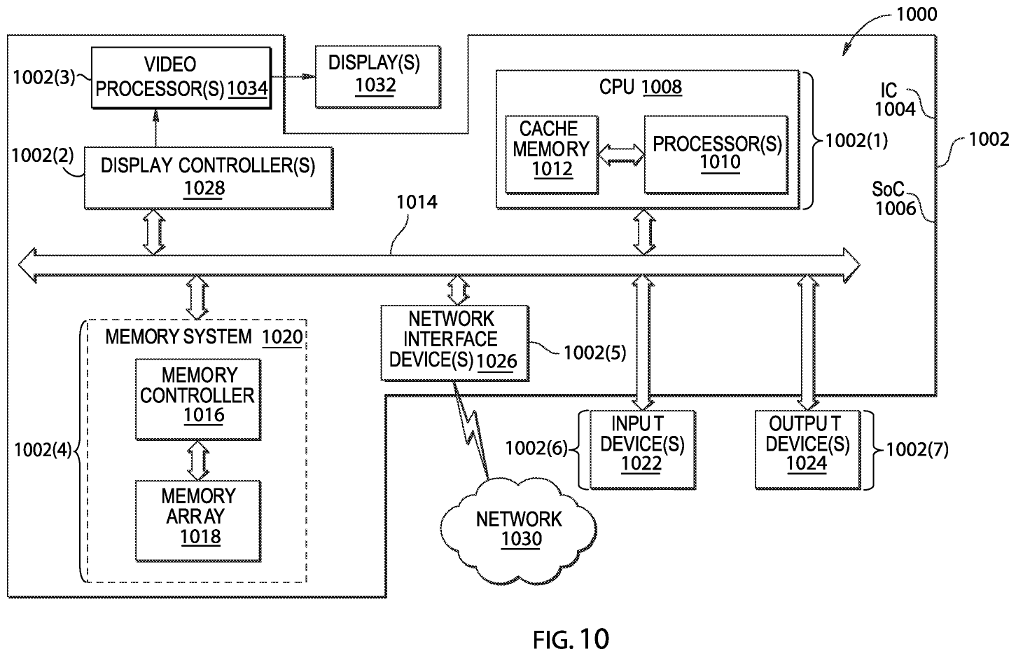

FIG. 10 illustrates a block diagram of an example of a processor-based system 1000 that can employ integrated circuits, including an acoustic filter that includes electrodes disposed on a piezoelectric layer on a first side of a first substrate and vias extending through the substrate to couple the electrodes to a second side of the substrate as illustrated in FIGS. 1 and 4F and according to, but not limited to, any of the exemplary fabrication processes of fabricating such acoustic filter in FIGS. 3 and 5A-5F. In this example, the processor-based system 1000 includes one or more central processor units (CPUs) 1002, which may also be referred to as CPU or processor cores, each including one or more processors 1004. The CPU(s) 1002 may have cache memory 1006 coupled to the processor(s) 1004 for rapid access to temporarily stored data. The CPU(s) 1002 is coupled to a system bus 1008 and can intercouple master and slave devices included in the processor-based system 1000. As is well known, the CPU(s) 1002 communicates with these other devices by exchanging address, control, and data information over the system bus 1008. For example, the CPU(s) 1002 can communicate bus transaction requests to a memory controller 1010 as an example of a slave device. Although not illustrated in FIG. 10, multiple system buses 1008 could be provided wherein each system bus 1008 constitutes a different fabric.

Other master and slave devices can be connected to the system bus 1008. As illustrated in FIG. 10, these devices can include a memory system 1012 that includes the memory controller 1010 and one or more memory arrays 1014, one or more input devices 1016, one or more output devices 1018, one or more network interface devices 1020, and one or more display controllers 1022, as examples. The input device(s) 1016 can include any type of input device, including, but not limited to, input keys, switches, voice processors, etc. The output device(s) 1018 can include any type of output device, including, but not limited to, audio, video, other visual indicators, etc. The network interface device(s) 1020 can be any device configured to allow an exchange of data to and from a network 1024. The network 1024 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1020 can be configured to support any type of communications protocol desired.

The CPU(s) 1002 may also be configured to access the display controller(s) 1022 over the system bus 1008 to control information sent to one or more displays 1026. The display controller(s) 1022 sends information to the display(s) 1026 to be displayed via one or more video processors 1028, which process the information to be displayed into a format suitable for the display(s) 1026. The display(s) 1026 can include any type of display, including, but not limited to, a cathode ray tube (CRT), a liquid crystal display (LCD), a plasma display, or a light-emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. As examples, the devices and components described herein may be employed in any circuit, hardware component, integrated circuit (IC), or IC chip. Memory disclosed herein may be any type and size of memory and may be configured to store any desired information. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. Alternatively, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using various technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

Implementation examples are described in the following numbered clauses:
1. A device, comprising:
   a first substrate comprising a first surface comprising a piezoelectric material;
   a first electrode disposed on the first surface;
   a second substrate;
   a first via extending through the second substrate and coupled to the first electrode; and
   a first circuit element electrically coupled to the first via and disposed between the second substrate and the first surface of the first substrate.
2. The device of clause 1, wherein the first circuit element comprises a capacitor.
3. The device of clause 1 or clause 2, wherein the first circuit element comprises an inductor.
4. The device of any of clause 1 to clause 3, wherein the first circuit element comprises an interconnect extending parallel to the first surface.
5. The device of any of clause 1 to clause 4, further comprising an insulating material disposed between the second substrate and the first surface of the first substrate, wherein the insulating material is disposed between the first circuit element and the first surface.
6. The device of clause 5, wherein the insulating material is further disposed between the first circuit element and the second substrate of the first surface.
7. The device of any of clause 1 to clause 6, further comprising a first air cavity between the first electrode and the second substrate.
8. The device of any of clause 1 to clause 7, wherein the first electrode is disposed in the first air cavity surrounded by the insulating material.
9. The device of clause 5 or clause 6, wherein the insulating material comprises a polymer.
10. The device of any of clause 7 to clause 9, further comprising a metal layer between the first air cavity and the second substrate.
11. The device of clause 10, wherein the metal layer is coupled to a terminal configured to couple to a reference voltage.
12. The device of any of clause 7 to clause 11, further comprising:
   a second electrode disposed on the first surface; and
   a second air cavity separate from the first air cavity between the second electrode and the second substrate.
13. The device of any of clause 7 to clause 12, further comprising:
   a third electrode in the first air cavity; and
   a fourth electrode in the second air cavity,
   wherein:
      the first and third electrodes comprise a first resonator having a first resonant frequency; and
      the second and fourth electrodes comprise a second resonator having a second resonant frequency.
14. The device of clause 12 or clause 13, further comprising at least a third air cavity.
15. The device of any of clause 12 to clause 14, further comprising:
   a wall comprising the insulating material disposed between the first air cavity and the second air cavity; and
   a second via disposed through the second substrate and through the wall and coupled to the second electrode.
16. The device of any of clause 1 to clause 15, wherein the second substrate comprises a material having a thermal conductivity greater than twenty (20) watts per meter-kelvin (W/(m·K)).
17. The device of any of clause 1 to clause 16, wherein the second substrate comprises a material having a thermal conductivity greater than thirty (30) watts per meter-kelvin (W/(m·K)).
18. The device of any of clause 1 to clause 17, wherein a thickness of the second substrate is in a range of sixty (60) to one hundred twenty-five (125) microns.
19. The device of any of clause 1 to clause 18, wherein the first via comprises a monolithic metal via.
20. The device of any of clause 1 to clause 18, wherein the first via comprises a cylindrical layer comprising a first metal and a core comprising a second material.
21. The device of any of clause 1 to clause 20, further comprising a contact on the second substrate, coupled to the first via, and configured to couple the first electrode to an external circuit.
22. The device of any of clause 1 to clause 21, wherein the second substrate comprises one of high-resistivity silicon (HRS), porous silicon (pSi), and alumina.
23. The device of any of clause 1 to clause 22, further comprising a filter comprising a surface acoustic wave (SAW) resonator comprising the first electrode coupled to the first circuit element, wherein the first circuit element comprises at least one of a metal-insulator-metal (MIM) capacitor and an inductor.
24. The device of any of clause 1 to clause 23 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
25. A method of fabricating a device, comprising:
   forming a first substrate comprising a first surface comprising a piezoelectric material;
   forming a first electrode on the first surface;
   forming a second substrate;
   forming a first via extending through the second substrate and coupled to the first electrode; and
   forming a first circuit element electrically coupled to the first via and between the second substrate and the first surface of the first substrate.
26. The method of clause 25, further comprising forming an insulating material between the second substrate and the first surface of the first substrate, wherein:
   forming the first circuit element further comprises forming the first circuit element on the second substrate; and
   forming the insulating material further comprises forming the insulating material on the first circuit element.
27 The method of clause 26, wherein forming the insulating material and the first circuit element further comprises:
   forming a first portion of the insulating material on the second substrate;
   forming the first circuit element on the first portion of the insulating material; and
   forming a second portion of the insulating material on the first circuit element.
28. The method of clause 25 or clause 26, further comprising:
   disposing the second substrate comprising the insulating material and the first circuit element on the first substrate comprising the first electrode,
   wherein forming the first via further comprises:
      forming a void through the second substrate and the insulating material to the first electrode; and
      forming a metal in the void.
29. An acoustic filter package, comprising:
   a package substrate; and
   a device comprising:
      a first substrate comprising a first surface comprising a piezoelectric material;
      a first electrode disposed on the first surface;
      a second substrate;
      a first via extending through the second substrate and coupled to the first electrode;
      a first circuit element electrically coupled to the first via and disposed between the second substrate and the first surface of the first substrate; and
      a contact coupling the first via to the package substrate.
30. The acoustic filter package of clause 29, wherein the first circuit element comprises one of a capacitor and an inductor.

What is claimed is:

1. A device, comprising:
a first substrate comprising a first surface comprising a piezoelectric material;
a first electrode disposed on the first surface;
a second substrate;
a first via extending through the second substrate and coupled to the first electrode; and
a first circuit element electrically coupled to the first via and disposed between the second substrate and the first surface of the first substrate.

2. The device of claim 1, wherein the first circuit element comprises a capacitor.

3. The device of claim 1, wherein the first circuit element comprises an inductor.

4. The device of claim 1, wherein the first circuit element comprises an interconnect extending parallel to the first surface.

5. The device of claim 1, further comprising an insulating material disposed between the second substrate and the first surface of the first substrate, wherein the insulating material is disposed between the first circuit element and the first surface.

6. The device of claim 5, wherein the insulating material is further disposed between the first circuit element and the second substrate of the first surface.

7. The device of claim 1, further comprising a first air cavity between the first electrode and the second substrate.

8. The device of claim 7, wherein the first electrode is disposed in the first air cavity surrounded by the insulating material.

9. The device of claim 5, wherein the insulating material comprises a polymer.

10. The device of claim 7, further comprising a metal layer between the first air cavity and the second substrate.

11. The device of claim 10, wherein the metal layer is coupled to a terminal configured to couple to a reference voltage.

12. The device of claim 7, further comprising:
a second electrode disposed on the first surface; and
a second air cavity separate from the first air cavity between the second electrode and the second substrate.

13. The device of claim 12, further comprising:
a third electrode in the first air cavity; and
a fourth electrode in the second air cavity,
wherein:
the first and third electrodes comprise a first resonator having a first resonant frequency; and
the second and fourth electrodes comprise a second resonator having a second resonant frequency.

14. The device of claim 12, further comprising at least a third air cavity.

15. The device of claim 12, further comprising:
a wall comprising the insulating material disposed between the first air cavity and the second air cavity; and
a second via disposed through the second substrate and through the wall and coupled to the second electrode.

16. The device of claim 1, wherein the second substrate comprises a material having a thermal conductivity greater than twenty (20) watts per meter-kelvin (W/(m·K)).

17. The device of claim 1, wherein the second substrate comprises a material having a thermal conductivity greater than thirty (30) watts per meter-kelvin (W/(m·K)).

18. The device of claim 1, wherein a thickness of the second substrate is in a range of sixty (60) to one hundred twenty-five (125) microns.

19. The device of claim 1, wherein the first via comprises a monolithic metal via.

20. The device of claim 1, wherein the first via comprises a cylindrical layer comprising a first metal and a core comprising a second material.

21. The device of claim 1, further comprising a contact on the second substrate, coupled to the first via, and configured to couple the first via to an external circuit.

22. The device of claim 1, wherein the second substrate comprises one of high-resistivity silicon (HRS), porous silicon (pSi), and alumina.

23. The device of claim 1, further comprising a filter comprising a surface acoustic wave (SAW) resonator comprising the first electrode coupled to the first circuit element, wherein the first circuit element comprises at least one of a metal-insulator-metal (MIM) capacitor and an inductor.

24. The device of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

25. A method of fabricating a device, comprising:
forming a first substrate comprising a first surface comprising a piezoelectric material;
forming a first electrode on the first surface;
forming a second substrate;
forming a first via extending through the second substrate and coupled to the first electrode; and
forming a first circuit element electrically coupled to the first via and between the second substrate and the first surface of the first substrate.

26. The method of claim 25, further comprising forming an insulating material between the second substrate and the first surface of the first substrate, wherein:
forming the first circuit element further comprises forming the first circuit element on the second substrate; and
forming the insulating material further comprises forming the insulating material on the first circuit element.

27. The method of claim 26, wherein forming the insulating material and the first circuit element further comprises:
forming a first portion of the insulating material on the second substrate;
forming the first circuit element on the first portion of the insulating material; and
forming a second portion of the insulating material on the first circuit element.

28. The method of claim 25, further comprising:
disposing the second substrate comprising the insulating material and the first circuit element on the first substrate comprising the first electrode,
wherein forming the first via further comprises:
forming a void through the second substrate and the insulating material to the first electrode; and
forming a metal in the void.

29. An acoustic filter package, comprising:
a package substrate; and
a device comprising:
a first substrate comprising a first surface comprising a piezoelectric material;
a first electrode disposed on the first surface;
a second substrate;
a first via extending through the second substrate and coupled to the first electrode;
a first circuit element electrically coupled to the first via and disposed between the second substrate and the first surface of the first substrate; and
a contact coupling the first via to the package substrate.

30. The acoustic filter package of claim 29, wherein the first circuit element comprises one of a capacitor and an inductor.
